(19) United States
(12) Patent Application Publication
(10) Pub. No.: US 2024/0411957 A1
(43) Pub. Date: Dec. 12, 2024

(54) SYSTEM AND METHOD FOR GENERATING A HIGH FIDELITY MODEL OF A CYBER PHYSICAL HUMAN SYSTEM

(71) Applicant: The Government of the United States of America, as represented by the Secretary of Homeland Security, Washington, DC (US)

(72) Inventors: Sean Warnick, Provo, UT (US); Alexandria Phounsavath, Fairfax, VA (US); Garfield Jones, Germantown, MD (US)

(73) Assignee: The Government of the United States of America, as represented by the Secretary of Homeland Security, Washington, DC (US)

(21) Appl. No.: 18/738,428

(22) Filed: Jun. 10, 2024

Related U.S. Application Data
(60) Provisional application No. 63/472,207, filed on Jun. 9, 2023.

(51) Int. Cl. G06F 30/20

(52) U.S. Cl. CPC G06F 30/20

(57) ABSTRACT

A system for building a high fidelity model of a cyber physical human system (CPHS) is disclosed. The CPHS modelling system may comprise a database containing database information and an interface configured to receive a schema and operational data from a user. The CPHS modelling system may comprise an assembler configured to: receive the schema and database information; and generate a generic model of the CPHS. The CPHS modelling system may comprise a machine learning module configured to: receive the operational data; execute a machine learning process; and use the operational data to generate the high fidelity model.

### CROSS-REFERENCE TO RELATED APPLICATIONS

This application claims the benefit of priority to U.S. Provisional Application No. 63/472,207 filed Jun. 9, 2023 incorporated by reference in its entirety.

### STATEMENT OF GOVERNMENT INTEREST

The present invention was made by employees of the United States Department of Homeland Security in the performance of their official duties. The U.S. Government has certain rights in this invention.

### FIELD

This application relates to systems and methods for modeling infrastructure.

### BACKGROUND

Models of phenomena are simplified descriptions or representations of those phenomena that offer insight in various ways. Often, they are used for counterfactual analyses, developing an understanding of how the phenomenon being modeled might behave under hypothesized conditions. Simple examples include many children's toys, such as a doll house or a model train. These toys enable children to visualize and explore how various hypothetical scenarios involving the doll house or model train might play-out, offering a sense of simulation as the children interact with the models.

Engineers use mathematical models of physical phenomena to apply physical laws to proposed structures, gaining an understanding for how the proposed structures will behave under various conditions. Buildings, bridges, dams, vehicles, tractors, water vessels, aircraft, rockets, missiles, satellites, robots, circuits, boilers, centrifuges, pacemakers, routers, radio equipment, and the Internet all are systems that leverage models in their development to gain a better understanding of how to approach design and what might be possible.

Ever since Kepler used mathematics to describe the motion of planets recorded by his mentor Tycho Brahe, and Newton leveraged that mathematics to quantify the notion of gravity and propose models for mechanics, mathematics has been the language scientists have used to describe their models. The curious fact that mathematics has proven so universally effective for modeling natural phenomena is discussed in Wigner's famous paper, “The Unreasonable Effectiveness of Mathematics in the Natural Sciences” (Wignar, 1960). More recently, computer scientists have spurned the methods traditionally used by physicists for building mathematical models in favor of automated machine learning approaches powered by large amounts of behavioral data (Halevy, 2009). Nevertheless, whether building mathematical models or computational ones, the same fundamental limitations about how they leverage information to make predictions apply.

Wigner, Eugene (1960). The unreasonable effectiveness of mathematics in the natural sciences. Communications in Pure and Applied Mathematics 13:1-14.

Halevy, A. Y., Norvig, P. & Pereira, F. (2009). The Unreasonable Effectiveness of Data. IEEE Intelligent Systems, 24, 8-12.

J. C. Willems, “The Behavioral Approach to Open and Interconnected Systems,” in IEEE Control Systems Magazine, vol. 27, no. 6, pp. 46-99, December 2007, doi: 10.1109/MCS.2007.906923.

Chetty, V., Warnick, S., Roy, S., & Das, S. K. (2020). Meanings and applications of structure in networks of dynamic systems. In Principles of Cyber-Physical Systems: An Interdisciplinary Approach (pp. 162-201). Cambridge Univ. Press. Control Systems Magazine vol. 27, no. 6, pp. 46-99.

U.S. Pat. No. 10,581,893 (Warnick et al.) directed to modeling of attacks on cyber-physical systems is incorporated by reference in its entirety.

U.S. Pat. No. 9,134,353 (Jia et al.) directed to Comfort-Driven Optimization of Electric Grid Utilization is incorporated by reference in its entirety.

U.S. Pat. No. 10,229,376 (Anderson et al.) directed to a Dynamic Contingency Avoidance and Mitigation System is incorporated by reference in its entirety.

U.S. Pat. No. 11,283,257 (Hong et al.) directed to Securing Against Malicious Control of Circuit Breakers in Electrical Substations is incorporated by reference in its entirety.

U.S. Patent Application Publication No. 2022/0407885 (Chiu et al.); directed to Systems and method for Providing Cybersecurity Analysis Based on Operational Techniques and Information Technologies is incorporated by reference in its entirety.

Modern infrastructures are complex engineered systems that deliver specific functionalities to their targeted user populations, often by combining cyber technologies with physical processes and human interventions. Examples include power systems, water treatment plants, transportation networks, gas pipelines, financial markets, and several other engineering applications.

Mathematical and computational models of these systems enable dynamic simulations revealing how the values of various quantities change over time and under a rich variety of potential operating conditions, quantifying the behavior of these infrastructures. This quantification of behavior can be useful for operational optimization, intrinsic vulnerability analysis, uncertainty quantification, contingency planning, counterfactual studies, and a host of other analyses supporting the design, operation, maintenance, and evolution of these systems.

Although such models of specific infrastructure systems are valuable for the general management of these systems, creating faithful models that produce accurate and reliable predictions of the behavior of the system can be difficult and expensive, usually requiring highly specialized expertise and intimate knowledge of the specific implementations of various machinery and software, and often a thorough understanding of how particular human operators do their jobs. This complexity is often prohibitive, so that it is rare to find an infrastructure system equipped with a high-fidelity model of its behavior.

This work describes a novel process for minimizing the cost and complexity for generating such models for infrastructure systems. The key is intelligent automation of certain steps of the process, exactly partitioning the information that must be provided from each source.

### SUMMARY OF THE INVENTION

In an exemplary configuration, a CPHS modelling system for a building a high fidelity model of a cyber physical human system (CPHS) is disclosed. In other words, a system and method for modelling a cyber physical human system is disclosed. The CPHS modelling system may comprise a database containing database information. The database may be configured to: obtain information about the cyber physical human system from a library; and store the information about the cyber physical human system into a partition. The library may be an open library and the partition may be publicly accessible. The CPHS modelling system may comprise an interface configured to receive a schema and operational data from a user. The CPHS modelling system may comprise an assembler configured to: receive the schema; receive the database information related to the schema; and generate a generic model of the cyber physical human system using the database information and schema; the generic model comprising an equation. The CPHS modelling system may comprise a machine learning module configured to: receive the operational data from the interface; execute a machine learning process; and use the operational data to generate a high fidelity model.

A method of generating a high fidelity model may comprise: receiving a schema and operational data from a user with an interface; obtaining information about the cyber physical human system from a library; storing information about the cyber physical human system into a partition of a database; generating a generic model of the cyber physical human system using the database information and schema; the generic model comprising an equation; receiving the operational data from the interface; executing a machine learning process; and using the operational data to generate the high fidelity model.

The CPHS modelling system may comprise a server comprising a processor, a housing, power supply, memory, and computer readable instructions; the computer readable instructions instructing the processor to interact with the database, generate the interface, execute the assembler, and manage the machine learning module.

The machine learning module may be configured to identify a parameter required to generate the high fidelity model from the generic model. The parameter may comprise a nature, type, date, time, and quantity. The machine learning module may be configured to determine an improved value (or define an undefined value) for the parameter required to generate the high fidelity model from the generic model. The machine learning module may be configured to determine specific operational data (called informative data) required to determine the improved value for the parameter. The improved parameter or defined parameter is a value for the parameter that, when used in a calculation of the equation in the model, generates a model result that is closer to an actual result than a model result using a default value or undefined value for the parameter. The machine learning module may be configured to: calculate a first model result by using a first value for the parameter to process the equation in the model; determine an actual result from the operational data; calculate a first difference in value between the model result and actual result; transform the parameter to a second value; calculate a second model result by using the second value of the parameter to process the equation in the model; calculate a second difference in value between the second model result and actual result; determine the second difference has a lower value than the first difference; and select the second value of the parameter for the high fidelity model. The machine learning module is configured to: receive a hyperparameter from the user; and adjust the machine learning process based on the hyperparameter. The CPHS modelling system may comprise a data manager configured to divide the operational data into learning data, validation data, and test data. The machine learning module is configured to: receive a hyperparameter from the user; and switch the machine learning process from a first mode to a second mode; wherein the first mode utilizing a slower, more precise solver, and the second mode uses a faster, less precise solver.

The parameter of the generic model may have a default value or an undefined value. The schema may specify components, interconnections between components, inputs to the components, and outputs to the components. The CPHS modelling system may comprise a schema converter configured to: receive the schema in a signal structure format; and convert the signal structure format schema to a substructure format schema.

The CPHS modelling system may comprise a model sufficiency analyzer configured to: determine what information is needed to generate a generic model; determine whether the public information from the open partition is sufficient to generate a generic model; determine the public information from the open partition is not sufficient to generate the generic model; and obtain proprietary information about the cyber physical human system from a proprietary source.

The CPHS modelling system may comprise a model sufficiency analyzer configured to: determine the assembler cannot build the generic model based solely on the public information in the open partition; obtain proprietary information from the proprietary partition; and supply the propriety information to the assembler.

The CPHS modelling system may comprise a model sufficiency analyzer configured to: determine the assembler cannot build the generic model based solely on the public information in the open partition; obtain private information from the private partition; and supply the private information to the assembler.

The database may be further configured to: store the proprietary information about the physical object in a proprietary partition; request permission from the proprietary source to use the proprietary information to generate a future model; and store the proprietary information in a private partition; the private partition containing the proprietary information and previously stored private information.

### BRIEF DESCRIPTION OF THE DRAWINGS

FIG. 1 is a schematic diagram of a CPHS modelling system.

FIG. 2 shows an operating environment for the CPHS modelling system.

FIG. 3A shows an example of a signal structure schema.

FIG. 3B shows an example of a subsystem structure schema.

FIG. 4 shows a schema builder.

FIG. 5 shows a schema converter.

### DETAILED DESCRIPTION

### Building a High Fidelity Model

### Model Behavior

Modeling begins by identifying a set of n observed quantities of interest, yᵢ, i=1,2, . . . , n. These quantities are often variables, with values that can change over time, so it becomes important to both identify whether time, t, is considered to evolve continuously, i.e., t∈ [symbol] = [symbol] , or whether time is considered to evolve in discrete steps at a uniform clock-rate, i.e., t∈ [symbol] = [symbol] . ∈ means element of. Also, it is important to identify the set of values, [symbol] , called the signal space, that each observed variable, yᵢ(t), can choose from at each time instant t. That is to say, if an observed variable yᵢ(t) measures the voltage in a circuit, then we might reasonably assume that time is continuous, and the measured voltages take values from the real numbers, i.e., yᵢ(t)∈ [symbol] = [symbol] , t∈ [symbol] . On the other hand, if the observed variable is the state of a particular traffic light, then we might still reasonably consider time to be continuous, but that measured values of the state of the traffic light take on values from a finite set, yᵢ(t)∈ [symbol] ={“red”, “yellow”, “green”}.

Once the relevant time axis, [symbol] , and a signal space, [symbol] ᵢ, for each of the observed variables has been identified, the behavior of the system, [symbol] , is the complete set of allowed combinations of observed variables. For example, a well-designed set of traffic lights at a four-way intersection would never allow all the lights to be green at the same time, so the behavior of these (four) lights would only allow one pair of opposite lights to be green when the opposite pair is red, and vice versa. Although the signal space for each light may be the triple “red”, “yellow”, and “green”, not all combinations of these values are allowed. This illustrates that the behavior of a system is generally a subset of the cross product of each observed variable's signal space, [symbol] ⊆ [symbol] ₁× [symbol] ₂× [symbol] ₃× [symbol] ₄.

Modeling a system amounts to characterizing the triple, { [symbol] , [symbol] , [symbol] } (Willems, 2007). Nevertheless, there can be many ways to describe the behavior of a system. That is to say, since the behavior of a system is a subset of the cross product of the observed variables' signal spaces, it should be clear that there can be many different ways to exactly characterize this subset. For example, suppose that a system has two observed variables, and the signal space for each of these variables is the set of real numbers. The cross product of these signal spaces is the vector space [symbol] ²2. Now, suppose that the behavior of this system is the subset of [symbol] ² given by the unit circle. One way to characterize this subset is [symbol] ={(y₁, y₂)| ∥y₁∥²+∥y₂∥²=1}, but another way is [symbol] ={(y₁, y₂)|(y₁(t)=sin(t), y₂(t)=cos(t)), 0≤t≤2π}, and there are many other ways to characterize the same set of points on the unit circle. Each of these different ways to characterize the system's behavior is a different model of the system. In summary, then, a system is characterized by its behavior, but there can be many different models that exactly characterize this same behavior. These models are called equivalent models.
t=time.
∈=element of.
[symbol] =relevant time axis.
[symbol] =“Bubble Z” means the integers, which are set of the values we allow a time variable, t, to take on when modeling discrete-time, or synchronous, systems.
[symbol] =a set of values called signal space.
yᵢ(t)=observed variable.
yᵢ=observed quantities of interest.
n=a natural number.
[symbol] =behavior.
[symbol] =Bubble R means the real numbers, which are the set of values we allow a variable, t, modeling time to take when modeling continuous-time or asynchronous systems.

$$= \{ ( {y}_{1} , {y}_{2} ) \vert {‖ {y}_{1} ‖}^{2} + {‖ {y}_{2} ‖}^{2} = 1 \}$$

$$= \{ ( {y}_{1} , {y}_{2} ) \vert ( {y}_{1} ( t ) = sin ( t ) , {y}_{2} ( t ) = cos ( t ) ) , 0 \leq t \leq 2 π \} .$$

$$( {y}_{1} , {y}_{2} ) \vert {‖ {y}_{1} ‖}^{2} + {‖ {y}_{2} ‖}^{2} = 1 \} = \{ ( {y}_{1} , {y}_{2} ) \vert ( {y}_{1} ( t ) = sin ( t ) , {y}_{2} ( t ) = cos ( t ) ) , 0 \leq t \leq 2 π \}$$

### Dependent and Independent Variables: Causality

Modeling begins by identifying a set of n observed quantities of interest, yᵢ, i=1,2, . . . , n, but sometimes some of these quantities are values that can be chosen or selected arbitrarily, while the others are derived from them. The variables that can be chosen arbitrarily are called independent, while the others are called dependent variables. Independent variables can be considered inputs to a system, and, since all quantities of interest are observed, or manifest, the dependent variables can be thought-of as outputs of the system. This input-output perspective of a system treats the system as a map from inputs to outputs, meaning that there exists some mechanism that computes the values of the dependent variables based on the values of the independent variables, a property called computational dependence. If the nature of this dependence satisfies particular constraints, namely, that values of the output variables at any time only depend on previous values of the input variables (i.e., not future values of the input variables), then we call the (computational) dependence of the outputs on the input variables causal. Causal models describe a mechanism for generating the behavior of the system, for computing the values of the outputs from values of the input variables, and equivalent causal models describe different mechanisms for making the same computation or generating the same behavior.

### Equivalent Models

Different models can describe the same behavior while offering varying degrees of information about the mechanism computing the relationship between input and output values that characterize the behavior. The minimal information capturing the mapping from inputs to outputs is referred to as a black-box model. The term black-box refers to the idea that it captures the input-output map but nothing else about the internal mechanism responsible for computing the behavior. At the other end of the spectrum, state machines, or state-space models, describe very specific procedures for computing output values of observed variables from initial values of internal state variables and trajectories of the input values specified from the initial time to the current time. These very specific procedures are one instance of a causal mechanism that computes the desired behavior. In general, there are many state-space models that are equivalent to a single black-box model; we call these state-space models realizations of the input-output map described by the black-box model, c.f. Chetty (2020).

Black-box models can be learned from informative input-output data, but there is not enough information in such data alone-no matter how much input-output data one collects—to specify the specific causal realization that generated the behavior. This is because of the many-to-one mapping between realizations and input-output maps (or, equivalently, black-box models or behaviors). In general, additional assumptions are required to identify the causal mechanism responsible for generating the data. So, while these different types of models are equivalent in the sense of the behavior they produce, they are not equivalent in terms of the information they offer about the causal mechanism computing this behavior. This discrepancy is manifest in the fact that the minimal number of parameters describing the black-box model is generally less than the minimal number of parameters describing a specific state-space realization of the black-box model; while number of parameters is not always a valid indication of model complexity, for many model classes it is an effective measure. In these cases, this increase in complexity required to specify causal mechanism demonstrates the level of ambiguity in observed measurements, and this ambiguity cannot be resolved from data recording observations of the system in operation. It is only resolved from a priori information discriminating which of the possible mechanisms capable of generating the behavior are actually responsible for generating the observed data.

### The Learning Problem

Typically, it is difficult to identify a model that describes the behavior of a system well enough to be useful. Often, we can appeal to rules of behavior that apply generally enough that we consider them to be “laws” or “first principles,” such as Newton's laws, but even these expressions are not specific expressions, but rather sets of models where each one is identified by the value of certain numbers in the expression. We call these numbers, parameters, and note that they serve as unique identifiers in a collection of models.

So, for example, one may want to model the motion of a block of wood or a brick lying on a smooth surface and decide that the appropriate first principles model would be F(t)=m* a(t), where F(t) is an independent variable describing the net force applied to the block at time t, and a(t) is a dependent variable describing the block's acceleration at time t, or the second derivative of its position with respect to time. This is not a single model, however-it is a set of models, each one identified by the value of the parameter m. Note that m is a constant and does not depend on the values of the other quantities in the expression. To choose a specific model characterizing the behavior of the specific block of wood or brick indented, we need to choose a value for m (or, equivalently, select a specific model from the entire set of models, model class, or “bucket” of models) and show that this model accurately predicts the acceleration of the block when subjected to various force profiles.

A learning problem may be a mathematical problem comprising a set of models, and data, a “notion of best.” A learning problem may comprise factors. A processor executing a learning algorithm to solve a learning problem may be configured to use the factors to identify one model from the set of models.

Each model in the set of models may comprise a number of parameters each model in the set of models. A learning problem comprising a model set, wherein the model set comprises a model with a variable number of parameters or a large number of parameters (e.g., more than a 100 parameters) is said to be nonparametric. A learning problem difficulty may be on how parameters are related to each other, how parameters are related to variables in the model, a “nature” of the available data, and an “intricacy” of the notion of best used to guide a selection. Note that nothing a priori demands anything stochastic or probabilistic about the problem; using statistics is merely a particular choice of models that enable an exceptionally rich interpretation of the results.

There are multiple types of learning problems such as machine learning problems, regression problems, classification problems, econometric problems, engineering problems, etc. A processor may be configured to solve a machine learning problem may select a model from a set of models; wherein the model comprises a class of functions; wherein the functions are. . . Examples of model classes include functions; most machine learning problems choose a class of functions for its model class, for example. Regression problems typically choose functions that map into a vector space, such as the real numbers. A processor may be configured to solve a regression learning problem may select a model from a set of models; wherein the model comprises a class of functions; wherein the functions map into a vector space of real numbers. Classification problems typically choose functions that map into a countable set, like the integers, or a finite set, like {“red”, “yellow”, “green”}. A processor may be configured to solve a classification learning problem may select a model from a set of models; wherein the model comprises a class of functions; wherein the functions map into a countable set such as integers or a finite set. Econometric and engineering system identification problems often choose sets of coupled differential equations, instead of functions, as their model classes. A processor may be configured to solve an econometric and engineering system identification problems may select a set of coupled differential equation as a selected model from the set of model. Special situations might choose relations of other types of maps as their “set of models.” In each case, however, the resulting problem is special case of the general learning Problem.

A computer may be programmed to solve a learning problem by implementing a learning algorithm A learning algorithm is a procedure that sifts through the models in the model class until it finds one it can present as “the answer” to the learning problem. Practically speaking, these algorithms iterate over values of the parameters in the models until specific criteria are met that cause the algorithm to declare success. Gradient descent is such an algorithm. It uses a particular function that maps from the parameter space characterizing the model class into the set of real numbers, called a loss function or objective function to give every model it considers a particular score. So, initializing with one set of parameter values starts the algorithm by scoring the model associated with that particular set of parameter values. It then chooses a new model from the set by nudging the parameters in a direction that would reduce the resulting “score,” as characterized by the loss function. It repeats this process until it can no longer decrease the score by nudging the values of the parameters. The resulting model, indexed by values of parameters at this “minimal loss” position is then returned as the “best.” For certain kinds of learning problems, this result may very well be the true answer and best model in the bucket. For other kinds of learning problems, however, this answer is not necessarily the model in the bucket with the very best score, called the “global optimum,” and instead is only a model with the best score in a particular region of the bucket, called a “local optimum.”

In situations where the learning algorithm delivers the true answer, we say that the algorithm is correct. Often, we use algorithms that are not provably correct, however, because the learning problems are too difficult to know how to design correct algorithms, or because the “local optima” are good enough.

### Training, Validation and Testing

The process a learning algorithm goes through to search through a set of models is called training. Training means. . . Learning means. A training algorithm may comprise a training process comprising the steps of A, B, C. A training algorithm may comprise a learning process comprising the steps of A, B, C. The algorithm will use the available data in this process to score different models in the bucket and use the results to decide where in the bucket to search next for even better models. Notice how the algorithm uses each part of the Learning Problem formulation—a bucket of models, data, and a notion of best—to find a solution to the problem. Since every set in the bucket is identified by a unique set of values of the parameters characterizing the set, this search process manifests itself as an iteration of different parameter values until they converge to the values associated with the model the algorithm decides is the best. This iteration motivates the terminology training and learning, repeatedly trying again and again until success is achieved.

Nevertheless, learning algorithms themselves may be characterized by values of their own parameters that affect how they conduct their search. A learning algorithm identifies a model that best fits sample data. The learning algorithm may adjust parameters of the model to improve data fit. Parameters or model parameter are learned during a machine learning phrase. Whereas hyperparameter are generally not learned during the machine learning phase. They are generally set forth beforehand. The parameters of a learning algorithm are called hyper-parameters, to distinguish them from the unique identifiers of each model in the set. Sometimes these hyper-parameters can also be “tuned” as part of the learning process, and the available data is partitioned into distinct subsets, a training and validation set, to facilitate this process of hyper-parameter tuning. Sample data may relate to distinct subsets including a training set, a validation set, and a test set.

Once a model from the set is selected by a training process utilizing the training data, administered by an algorithm whose hyper-parameters have been tuned utilizing the validation data, it becomes important to measure the performance of this model against an entirely new set of data called test data. Test data is a third subset of the available data, set aside as a mechanism for scoring the performance of the final model selected by the learning algorithm.

### Digital Twins

The types of models described here are designed to accurately mimic the behavior of real systems. In that sense, they become virtual representations of real physical objects and processes and might be considered digital twins of these physical things. A digital twin may be a digital model or virtual model of an intended or actual real-world physical product, system, installation, or process. The digital twin may be used for simulation, integration, testing, monitoring, maintenance, etc. Product lifecycle management processes may use a digital twin. A digital twin may exist before the real world object by a process called virtual prototyping. A digital twin of an existing entity may be used in real time and regularly synchronized with the corresponding physical system. Optionally, a digital twins may provide a visual representation of the physical objects and processes in a virtual world and have real time sensors actively updating model parameters. The term high-fidelity simulation or predictive model will be used to specifically designate a digital twin that provides a visual representation of the physical objects and processes in a virtual world or has real time sensors actively updating model parameters.

### Intelligent Automation for Model Building

A CPHS modelling system may be configured to build a model of physical objects such as ports, chemical facilities, power plants, commercial buildings, military bases, HVAC systems, treatment plants, agriculture supply chain systems, manufacturing facilities, critical infrastructure, etc. Some physical objects (as critical infrastructure) may comprise complex systems. Physical objects may comprise a plurality of integrated physical processes with cyber technologies and human interactions. An entity seeking to build a high-fidelity predictive model of a physical object may face challenges such as retaining skilled staff. Significant expenses associated with labor and equipment may be needed to build a high-fidelity model Systems, methods, algorithms, and techniques are provided using intelligent automation to simplify and reduce costs associated with generating high fidelity predictive models of physical objects such as critical infrastructure.

### Defining a Schema

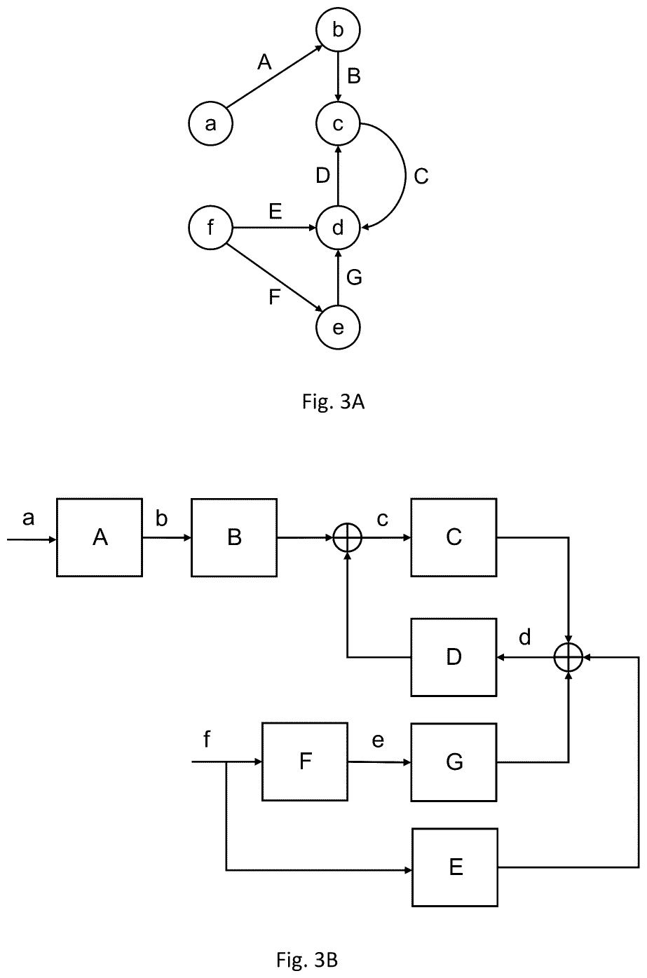

A cyber physical human system may be represented by a schema. A schema may comprise specific types of components, interconnections between components, inputs to the components, and outputs to the components. A schema may be represented in signal form (FIG. 3A) or subsystem form (FIG. 3B).

A subsystem form may refer to the topology of a system constructed as the interconnection of multiple component subsystems. A user of the CPHS modelling system may provide the CPHS modelling system a schema containing information about a specific system that the user wants to model. The user may provide the schema via an interface.

A substructure structure schema (also known as a subsystem schema or block diagram) provides the names the names of the components (A-G). The edges are signals (inputs and outputs of the components.) The subsystem schema also specifies how the components are interconnected. A subsystem schema may comprise a summing junction, show as a circled “plus sign.” The summing junction may be configured to add the input signals to produce the output signal, indicated by the direction of the arrows either into or away from the summing junction.

The signal structure drawing (FIG. 3A) represents the names of signals as lower case letters (a-f) and components in capital letters A-G.

A signal structure schema is provided by communicating the structure of a system by identifying the manifest variables, as one does when building a model, but determining how those variables depend causally on each other. This view of a system reveals its signal structure, or relationship between signals, and it is common in scientific applications, like microbiology or economics, where one doesn't really know the underlying mechanism or how to describe it as an interconnection of subsystems. As a result, the dynamics between manifest variables act almost like subsystems and can often be treated as such. In situations where the subsystem structure is not known for a particular infrastructure, learning the signal structure from data may prove to be an alternative.

### Schema Builder

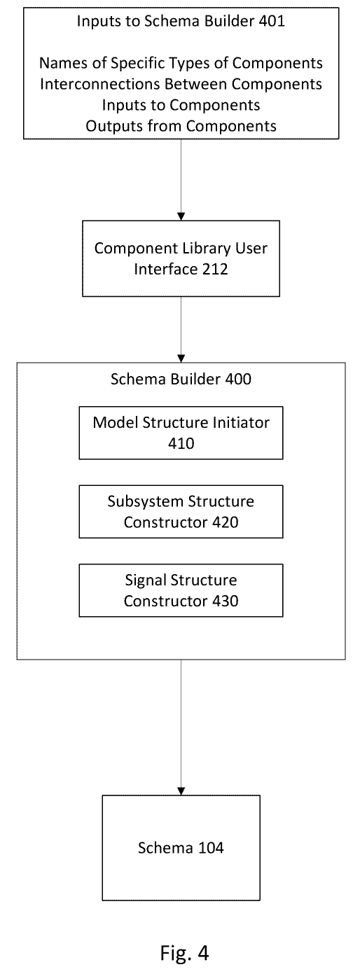

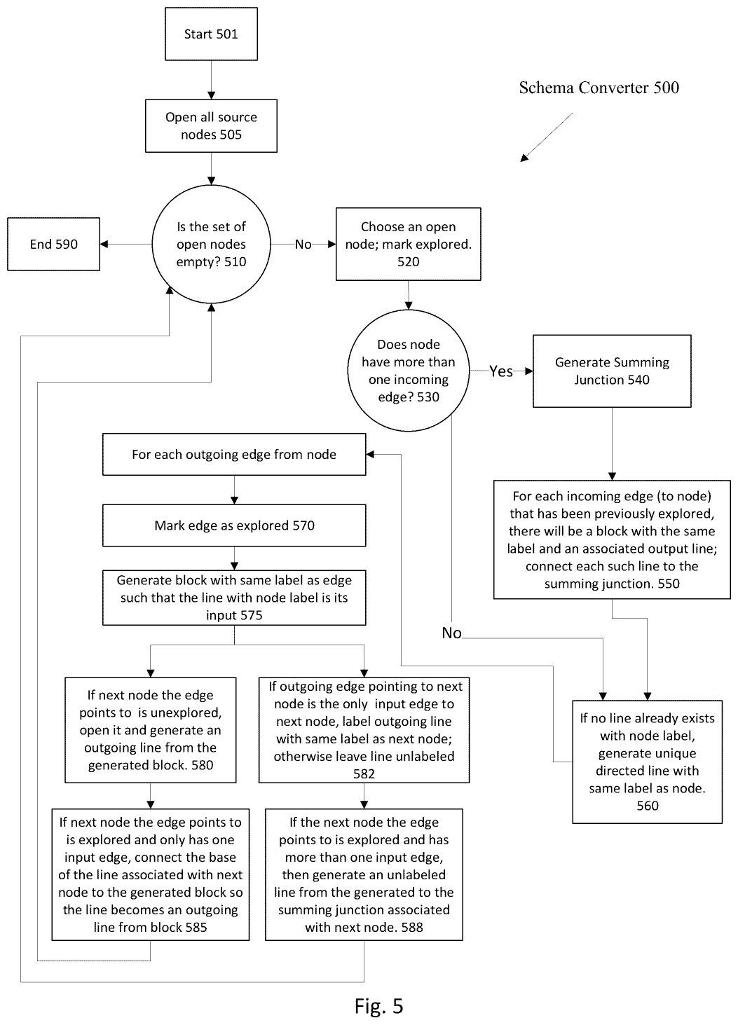

FIG. 4, in some configurations of the CPHS modelling system may comprise a schema builder 400. A schema builder is a tool built into component library user interface 212 (for example) that allows a user to build a schema 104 based on his or her working knowledge of the CPHS the user wants to model. The schema builder 400 may comprise or be connected to the component library user interface 212. The schema builder may be configured to receive (optionally through the interface) inputs to the schema builder 401 such as names of specific types of components; interconnections between components, inputs to components, and outputs from components. The schema builder 400 may comprise a model structure initiator 410, a subsystem structure constructor 420, and a signal structure constructor 430.

The schema builder 400 may be configured to generate a subsystem structure schema. In an exemplary configuration, the schema builder comprises at least one of the model structure initiator and a subsystem constructor. The model structure initiator may be configured to: (i) identify a first subsystem, second subsystem, third subsystem, and a fourth subsystem of the physical object using data from at least one of the open partition, previously stored information from the private partition, and proprietary partition; and (ii) identify a first signal, second signal, a third signal, a fourth signal, fifth signal, a sixth signal, and a seventh signal of the physical object from at least one of the open partition, previously stored information from the private partition, and proprietary partition. The subsystem constructor may be configured to: (i) generate a subsystem schema; (ii) receive data from the intake system; (iii) render the first subsystem; (iv) connect the first signal as an input to the first subsystem; (v) render the second subsystem; (vi) connect the second signal as output of the first subsystem and input into the second subsystem; (vii) render the third subsystem; (viii) connect the third signal as an output of the second subsystem and an input to a first summing junction; (ix) connect the fourth signal as input into the third subsystem and output of the first summing junction; (x) connect the fifth signal as an output of the third subsystem and an input to the second summing junction; (xi) render the fourth subsystem; (xii) connect the sixth signal as an output of the second summing junction and an input to the fourth subsystem; (xiii) connect the seventh signal as output of the seventh subsystem and input to the first summing junction; (xiv) render the subsystems as geometric shapes; [symbol] [symbol] [symbol] [symbol] [symbol] rendering the signals as lines; [symbol] [symbol] [symbol] .

The schema builder may be configured to generate a signal structure schema. In an exemplary configuration, the schema builder comprises at least one of the model structure initiator and a signal constructor. The model initiator may be configured to: (i) identify a first subsystem, second subsystem, third subsystem, and a fourth subsystem of the physical object using data from at least one of the open partition, previously stored information from the private partition, and proprietary partition; and (ii) identify a first signal, second signal, a third signal, a fourth signal, fifth signal, a sixth signal, and a seventh signal of the physical object from at least one of the open partition, previously stored information from the private partition, and proprietary partition. The signal structure constructor may be configured to: (i) generate a signal structure schema; (ii) receive data from the intake system; (iii) render the first signal as a first node and the second signal as a second node; (iv) connect the first subsystem as output of the first node and an input into the second node; (v) render the third signal as a third node; (vi) connect the second subsystem as output of the second node and input to the third node; (vii) render the third signal as a fourth node; (viii) connect the third subsystem as an output from the third node and an input into the fourth node; (ix) connect the fourth subsystem as an output from the fourth node and input to the third node; (x) render the nodes as having an oval shape; and (xi) render the subsystems as lines.

### Schema Converter

Some configurations of the CPHS modelling system may comprise a schema converter 500 configured to convert schema in a signal format into subsystem structure schema format. The process starts at 501. The schema converter may be configured to open a source node (or all of them) 505. If there are no more nodes left 510, the process ends 590. While there are nodes left, the schema converter may choose an open node and optionally mark that node explored. The schema converter may determine whether is more than one incoming edge. 530 If there is more than one incoming edge, the schema converter may generate a summing junction. For each incoming edge (to node) that has been previously explored, the schema converter may (i) create a block with a label and an associated output line; and (ii) connect each such line to the summing junction. 550. If no line already exists with node label, the schema converter 500 may generate a unique directed line with the same label as the node. 560

For each outgoing edge from node: the schema converter may mark edge as explored 570; and generate a block (the “generated block”) with the same label as the edge such that the line has a node with the same label is its input 575. If a next node that the edge points to is unexplored, the schema generator may open it and generate an outgoing line from the generated block 580. If the outgoing edge pointing to the next node is the only input edge to next node, the schema converter may label the outgoing line with the same label as next node. If the outgoing edge pointing to the next node is not the only input edge to next node; the schema converter may leave line unlabeled. 582

The schema converter may connect the base of the line associated with the next node to the generated block so the line becomes an outgoing line from the generated block; if the next node the edge points to has been explored and only has one input edge. 585 The schema converter may generate an unlabeled line from the generated block to the summing junction associated with next node; if the next node the edge points to has been explored and more than one input edge. 588

### CPHS Modelling System Overview

The CPHS modelling system may comprise various computers and software. The CPHS modelling system may be “cloud enabled” so that users can access the CPHS modelling system from various locations. The hardware for the server or computer may comprise a processor, memory, network interface, system bus, peripherals, displays, hard drives, and software stored in the memory and configured to cause the processor to execute instructions. A computer can be a server farm, data warehouse, server, laptop, personal computing device, handheld computer, wearable, etc.

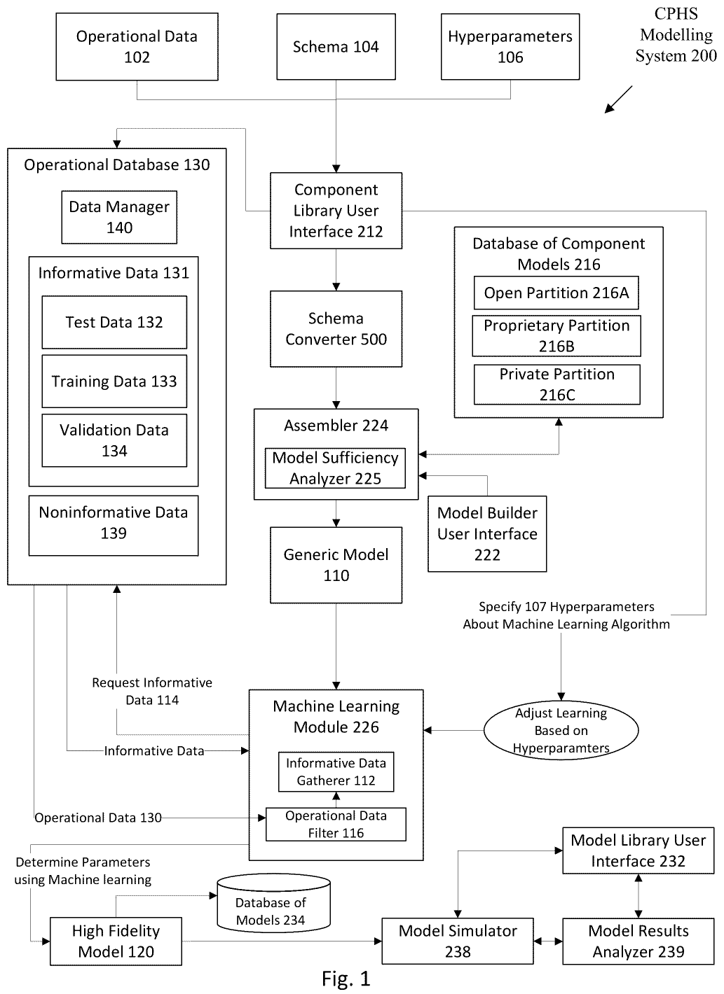

FIG. 1 shows an exemplary view of a configuration of the CPHS modelling system 200. At a high level, the CPHS modelling system may be configured to generate a high fidelity model 120 from user supplied operating (operational) data 102 and a schema 104. The user may specify 107 a hyperparameter 106 that controls how the machine learning module 226 applies its machine learning processes. The user may interact with a computer generated interface (component library user interface 212). The component library user interface 212 may contain programming or control designed to receive the operating data and schema. In some configurations, the operating data may be provided to the interface through an API. In some configurations, the user may build the schema using the CPHS modelling system with a schema builder. The CPHS modelling system may comprise a schema converter 500 configured to convert schema from a first format to a second format.

An operational database 130 may be configured to receive operating data from the component library user interface and/or the CPHS modelling system. The operational database may be an integrated component of the CPHS modelling system. A data manager 140 may be configured to organize how data is stored in the operational database 130. For example, the data manager 140 may be configured to flag or label certain data as informative data 131 and some data as noninformative data 139. Informative data 131 may be useful for the machine learning process to learn or determine a value for a parameter, whereas noninformative data 139 might not be useful for the machine learning process to learn or determine the value for the parameter. As shown informative data can contain test data 132, training data 133, and validation data 134.

The CPHS modelling system 200 may comprise a database of component models 216. This database may comprise an open partition 216A, proprietary partition 216B, and a private partition 216C.

An assembler 224 may be configured to gather data from the database of component models 216 to generate a generic model 110. The user may interact with a model builder user interface 222 to control assembly of the user model. The user may access a terminal or a computer which displays the model builder user interface 222 and component library user interface 212. The assembler 224 may comprise a model sufficiency analyzer 225 configured to determine whether database of models comprises sufficient component model information to generate a generic model. The determination may be limited to a specific partition such as the open partition.

The machine learning module 226 may be configured to access the generic model. The machine learning module 226 may be configured to determine what informative data that the machine learning module's machine learning process can use to determine one or more parameters of the generic model. An informative data gatherer 112 may be configured to generate a request for this informative data (e.g., SQL request.) This process may be referred to as tuning the generic model. The machine learning module 226 may request 114 informative data from the user, operational database 130, CPHS modelling system 200, etc. The operational database 130 (for example) may respond to the request by providing specific informative data. In some configurations, the machine learning module 226 may request operational data and use an operational data filter 116 to remove noninformative data from the operational data. In some configurations, the machine learning module may request a subset of the operational data from the operational database. The operational data filter may be configured what types of informative data can be used by the machine learning module to define the value for the parameter.

The machine learning module may comprise various machine learning algorithms. The user may specify what types of algorithms the machine learning module uses. For example, the machine learning module may comprise a slow solver and fast solver. The user may control certain how the machine learning module implements its machine learning module through specifying one or more hyperparameters. Through tuning the generic model and resolving (determining) one or more parameters in the generic model, the machine learning module may generate a high fidelity model 120 of the cyber physical human system. The machine learning module may store the high fidelity model 120 in a database of models 234.

The user (or a different user) may interact with the high fidelity module through a model library user interface 232. The model library user interface may control a model simulator which can simulate the high fidelity model. The user can leverage the model library user interface to run various tests in various conditions to predict how a real CHPS would react under similar conditions. The user would provide test conditions to the model simulator 238; the model simulator would solve various equations to determine high fidelity results and provide the high fidelity to the user via the model library user interface 232. Finally, the CPHS modelling system may comprise a model results analyzer 239 configured to determine performance of the high fidelity model by instructing the model simulator to solve various equations using test data.

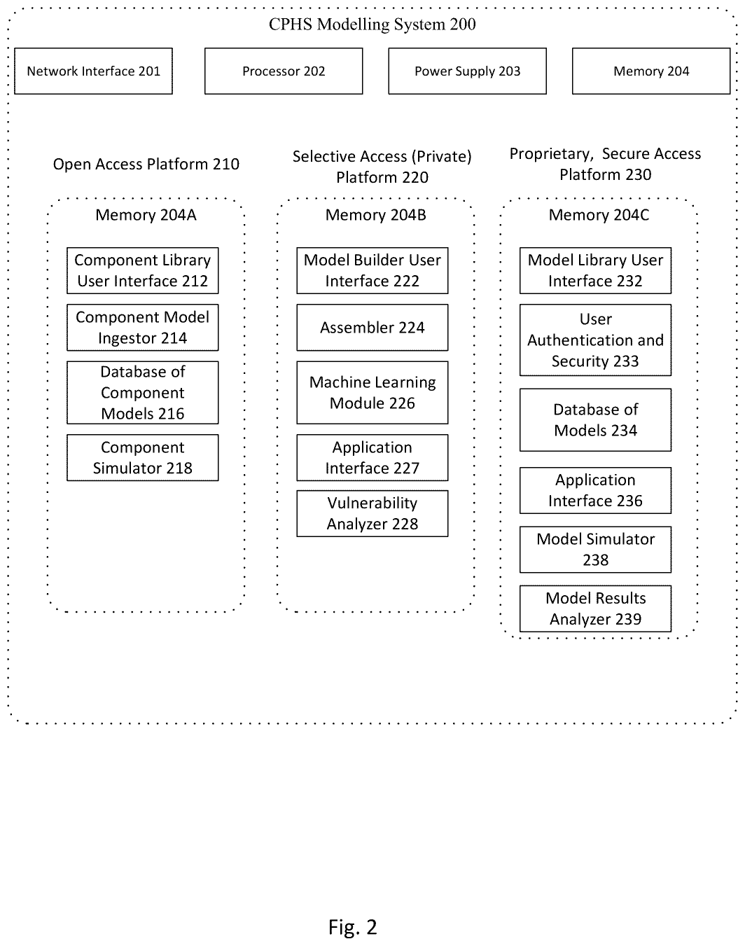

FIG. 2 show a view of the computing architecture for an exemplary configuration of the CPHS modelling system. The CPHS modelling system may be configured as a single cloud computing architecture. The CPHS modelling system may comprise computers (such as servers). The servers or server farm may power, execute, run, generate, etc. the open access platform 210, selective access platform 220, and proprietary/secure access platform 230 (collectively, the “platforms”). In some configurations, memory units 204A, 204B, 204C may be “subunits” of a single memory 204. In other configurations, memory units may be distinct units. The same is true with other computing components. In some configurations, the platforms may be powered by their own individual server and memory, and in other configurations a single server or network of servers powers the platforms through techniques such as distributed computing. The data modeling system may also contain other computing hardware such as a network interface 201, a processor 202, and a power supply 203, etc.

The term “component” is used in at least three contexts in this application. A Cyber physical human system (CPHS) has components. A powerplant, for example, may have components such a computing cluster, transformer components, electric generators, etc. A schema of a powerplant would have components that represent the computing cluster, transformer components, and electric generators. Additionally, the computer and cloud computing system also may comprise components such as a component model ingestor or component simulator. More broadly, a system comprises components and components may comprise subcomponents.

### Platforms

Referring to FIG. 2, each of the platforms is shown as having certain distinct components. For example, the open access platform comprises a component library user interface 212, component model ingestor 214, database of component models 216, and a component simulator 218. The selective access platform 220 comprises a model builder user interface 222, an assembler 224, a machine learning module 226, an application interface (API) 227, and vulnerability analyzer 228. The proprietary, secure access platform 230 comprises model library user interface 232, user authentication and security 233, database of models 234, application interface 236, model simulator 238, and model results analyzer 239.

However, the above described configuration is exemplary only. Some implementations of the invention might not contain all these components. Moreover, some platforms may contain components from other platforms. For example, the selective access platform could contain the model library user interface 232 and model simulator 238. Some implementations may contain a different number of platforms than the example shown (1 platform, 2 platforms, 4 platforms, 5 platforms, 10 platforms, etc.) Each of the platforms may contain different levels of user access and rights and have different parts. The selective access platform 220 and proprietary, secure access platform both contain an API, but the open access platform is not shown as containing an API, however such configurations are contemplated. Moreover, the selective access platform and proprietary platform could be a single platform, in some configurations.

In the example shown, the open access platform might be accessible to all users, but access to the component library user interface might require an account. The account may or may not have a related service fee. The component library user interface may provide a user with access to certain components of the open access platform 210. There are various types of interfaces described in this specification. The component library user interface 212 may be configured to allow the user to provide the CPHS modelling system with certain information such as the schema, hyperparameters, and operational data.

### Component Library User Interface

Referring to FIGS. 1 and 2, the component library user interface 212 may be configured to allow users to upload operational data 102, a schema 104, and hyperparameters 106. Additionally, the component library interface may be configured to allow the user to control the component model ingestor 214, access the database of component models 216, and run the component simulator 218.

### Component Model Ingestor

The component model ingestor 214 may be hardware or software configured to ingest component models from component sources (such as vendors or entities that build CPHS components). For example, the component model ingestor may have an optional API configured to provide utility vendors with software that facilitates sharing of component data with the component model ingestor. The component model ingestor 214 may be configured to receive a component model from a component source, generate and sequence equations in the component model, and store the component model in the database of component models.

As previously described, a CPHS has a plurality of components. Each of these components may be represented as its own model, called a component model. A generic model of a CPHS may comprise a plurality of component models.

### Database of Component Models

The database of component models 216 may comprise component models generated by the component model ingestor 214. The database of component models may comprise an open partition, proprietary partition, and private partition. A partition in a database is a logical grouping of data. In this case, the grouping of data is open access, proprietary, and private. The open partition 216A for open access may be configured to store component models accessible to users of the open access platform. The proprietary partition 216B may be configured to restrict access to component models only to members that provided the component data to the component model ingestor. The private partition 216C (or selective access partition) might comprise component models of proprietary data (from a vendor of CPHS component for example), wherein the owner of the proprietary data elected to share the proprietary data/proprietary component model with the CPHS modelling system 200. Component models in the selective access partition (private partition) may be accessible to certain users with enhanced access rights (licensed users, users that paid a fee for using the CPHS modelling system 200, etc.) In some configurations, the CPHS modelling system 200 may be configured to track ownership of component models in the private partition. The CPHS modelling system 200 may be configured to pay a royalty or payment to the component source (e.g., a component vendor) that distributed the proprietary component model to the component model ingestor. The CPHS modelling system 200 may charge a user an access fee for accessing the proprietary component model. The CPHS modelling system 200 may generate money by charging a higher access fee than the royalty.

### Model Sufficiency Analyzer

In some configurations, the CPHS modelling system 200 may comprise a model sufficiency analyzer 225. The model sufficiency analyzer may be a component of the assembler 224 for example. The model sufficiency analyzer 225 may be configured to determine what information is needed to generate a generic model; determine whether the public information from the open partition is sufficient to generate a generic model; determine the public information from the open partition is not sufficient to generate the generic model; and obtain proprietary information about the cyber physical human system from a proprietary library. The model sufficiency analyzer 225 may be configured to: determine the assembler cannot build the generic model based solely on the public information in the open partition; obtain proprietary information from the proprietary partition; and supply the propriety information to the assembler. The model sufficiency analyzer may be configured to determine the assembler cannot build the generic model based solely on the public information in the open partition; obtain private information from the private partition; and supply the private information to the assembler. The database of component models 216 may be configured to store the proprietary information about the physical object in a proprietary partition; request permission from the proprietary source to use the proprietary information to generate a future model; and store the proprietary information in a private partition; the private partition containing the proprietary information and previously stored private information.

### Component Simulator

The component simulator 218 may be configured to solve equations in the model; display the component model; accept inputs to the model to generate outputs from the component model.

### Model Builder User Interface

The selective access platform 220 may comprise a model builder user interface 222. The model builder user interface may be configured to control the assembler 224, control the machine learning module 226, control the API 227, and control the vulnerability analyzer 228. As a user interface, the model builder user interface can send and receive information to and from subcomponents in the selective access platform (assembler 224, machine learning module 226, etc.)

### Assembler

The assembler 224 may be configured to receive a schema from a user. The assembler may be configured to receive a schema from the user. The assembler 224 may access the database of component models to obtain component models specified by the schema. The assembler may be configured to generate a generic model (possibly with default or undefined parameter) based on the component models. The component models may comprise one or more equations. As a result, the generic model may comprise a plurality of interrelated equations. A parameter may be a constant in one or more of these equations.

The assembler may be an “intelligent” assembler in that it can be configured to integrate different kinds of information available from the information partition. In an example, process, the component model ingestor 214 may be configured to obtain component models of a generator model, a transformer model, and a transmission line model into the database of component models 216 (optionally from a public domain source). The CPHS modelling system 200 may be configured to model a specific regional power system for example. The assembler 224 might control or signal the component model ingestor to request the operator of the regional power system operator to provide proprietary information about the regional power system. An API could be connected to a system of the operator (propriety model source) to facilitate ingestion through the component model ingestor. The ingestor may store the proprietary component models in any of the three partitions (the open partition 216A, proprietary partition 216B, or private partition 216C). The assembler may store the assembled generic model in any of the three partitions (the open partition 216A, proprietary partition 216B, or private partition 216C). The assembler 224 may comprise a user-selectable option that provides the user (operator, source) with an option to store the data in one of these partitions. In some configurations, the CPHS modelling system 200 may be configured to determine which partition to store the proprietary component model automatically. For example, the CPHS modelling system may store all information from a proprietary source and all models generated using proprietary information into a proprietary partition. The CPHS Modelling system may provide the user with an option to store the component model or generic model in a private partition or proprietary partition. In some configurations, the CPHS modelling assembly may charge a second user a fee to use data from a first user that was stored in the private partition. The CPHS modelling assembly may prohibit a second user from accessing data stored by a first user in the proprietary partition.

### Machine Learning Module

The model builder user interface 222 of the CPHS modelling system 200 may control the assembler 224 to generate a generic model. The model builder user interface 222 may also control the machine learning module 226 to generate high fidelity model. A high fidelity model 120 provides more precise/more accurate results than a generic model 110. For example, a user of the model library user interface 232 may instruct the model simulator 238 to determine how long an engine will last if the oil isn't changed. A car is an example of a cyber physical human system (CPHS). One of the parameters of such a model might be the ambient average temperature of the engine. The machine learning module 226 can determine that it generate a more precise model if it factors in the average ambient temperature to the model equations. The machine learning module 226 may comprise an informative data gatherer configured to determine what informative data would improve the accuracy or precision of the model. The informative data gather 112 may also request 114 the user provide the informative data such as average ambient temperature to develop a tuned model (the high fidelity model). In some configurations, the machine learning module 226 may comprise an operational data filter 116 configured to filter out noninformative data 139 from informative data 131. In some configurations, the informative data gatherer 112 is configured to analyze the operational data 102 to determine which informative data 131 to request and instruct the informative data gatherer request the user provide that informative data.

The machine learning module may be configured to determine what type, nature, dates, times, and quantities of operational data (operational data may comprise informative data or non-informative data) may be necessary to determine values or improved values for the parameters. Nature may relate to physical, electrical, or mechanical properties, conditions, or characteristics of a subcomponent of a component being modelled (a worn and rusted pipe). Type may relate to a classification of the subcomponent within a larger class (a PVC pipe is a class of pipes). The machine learning module may be configured to request the informative data needed to determine values for the parameters from the user and/or database. The user may supply the operational data via the interface to the machine learning module.

The machine learning module may also be configured to determine factors about the operational data such as nature, type, date, time, and quantity of the informative data that may be needed to determine values (improved values) for the parameter(s). E.g., the request may request the database specify how much voltage existed in a transformer on a certain date and time. Or the request may request the user provide what the change in voltage was in response to an increase in power requirements when ambient temperatures were 10 degrees higher than average temperature.

A model may contain a parameter and a generic model may contain a default value or undefined value for one or more parameters. An example of parameter may be a flow rate through a specified pipe on a certain date and time. In this example, the type is flow rate, nature is the specific pipe, etc. Or a parameter could specify a number of disruptions in flow rate in a specified pipe with a time window. In the latter example, the number of disruptions is an example of quantity. The time window are dates and times. Through machine learning, a CPHS modelling system (or the machine learning module) may define, improve, or determine an improved value for the parameter(s). The machine learning module may be configured to determine which specific operating data is informative for determine a value for the parameter such as the nature, type, quantity, time, and date of the operating data.

In this context, an improved parameter is a value for a parameter that, when used in the calculation of the equations in the model, generates a model result that is closer to the validation data (or other test data) than a model result using the default parameter. In other words, the machine learning module may determine an error range between a model result using the default parameter and the validation result. (An error range being a difference in value between a model result, determined by using a default parameter in processing equations in a model vs the actual result which is set forth in the operational data (e.g., validation data)).

The machine learning module may also request the user or the database specify a hyperparameter(s) that controls how the machine learning module calculates the improved value for the parameters. For example, the hyperparameter may specify settings in a solver used to generate the improved value for the parameter. The setting, for example, may cause the solver to switch between a slow, precise mode and a fast, imprecise mode.

### Informative Data

Data supplied to the machine learning module may be stored in an operational database 130. Said operational database configured to store operational data. The database may organize the informative data as test data 132, training data 133, and validation data 134. The machine learning module 226 may be configured to use training data to determine value for the model parameters. The machine learning module may be configured to use the training data to fit or transform the parameters of the model. The machine learning module may be configured to use the validation data to tune the parameters of a model, for example to choose the number of valves in a pipe assembly. The machine learning module may be configured to use test data assess performance of a high fidelity module.

### Model Library User Interface & Model Simulator

The user may perform testing of the high fidelity model by interfacing with the model library user interface 232. The model library user interface 232 may instruct the model simulator generate an instance of the high fidelity model 120. The model library user interface can determine performance of the high fidelity model. The model library user interface may access the test data or the user may provide test data. The model library user interface 232 may be configured to provide the test data to the model simulator 238. The model simulator 238 may solve various equations in the high fidelity model 120 using the test data.

### Model Results Analyzer

A model results analyzer 239 may be configured to generate a first model result using the test data. The model results analyzer 239 may compare (determine a difference between) the first model result and the actual result contained in the test data. Through generating a comparison between the first model result and the actual result, the model results analyzer 239 can determine accuracy or performance of the high fidelity model. The model results analyzer 239 may be configured to grade the performance of the high fidelity model based on (for example) the average difference between a plurality to model results and actual results.

### Examples of Embodiments

There are a variety of options for deploying the Intelligent Automation for Model Building. In addition to separate clouds, the Intelligent Automation can be deployed in a single cloud, hybrid of cloud and on-premises environments, or even a single machine. The environment required for deployment depends on the scale of the problem, where data can live and be processed, and other requirements of specific owners and operators.

The use cases vary greatly beyond power generation vulnerabilities to apply to cyber-physical systems at large. Rapid, specific modeling to create high fidelity models for water distribution systems provide similar insights into the network of pumps, storage, distribution networks, etc. to assess vulnerabilities specific to a single system. No two water distribution systems are alike so that the specific vulnerabilities will vary from system to system. This concept can be extended to systems within chemical, transportation, food and agriculture, and other sectors, providing high value information to their owners and operators.

Intelligent automation applies to modeling single systems, but the approach provides additional, critical value in rapidly modeling interconnections between system intersections to understand cascading effects of system failure, such as the intersection of water and electric power systems.

In addition to identifying vulnerabilities, Intelligent Automation for critical infrastructure can help owners and operators identify the most effective solutions (e.g., subcomponent parts, changes to practices) to address the vulnerabilities, in addition to potentially discovering new ones introduced by these changes. Intelligent automation can also take advantage of cost data specific to a system to inform cost effective solutions to address vulnerabilities. This follow-on use produces specific costs for installing, deploying, and operating with these changes in the system.

### Related Technologies

### AutoML

In recent years, automated machine learning (autoML) capabilities have decreased the time to apply models to data, akin to specialized data preparation tools decreasing the time for analysts to prepare data for analysis. AutoML applies many algorithms to data at once to produce many models to answer a question (e.g., classification, regression). However, autoML does not assemble the data of component parts of a system to build a comprehensive, high-fidelity model. Applying AutoML for creating high-fidelity models, as described for Intelligent Automation, would still require highly manual steps to reflect comprehensive behavior of systems that have cascading vulnerabilities under different scenarios. In short, while autoML might be part of the process of creating high fidelity models via Intelligent Automation, autoML is not a compiler of data representing critical infrastructure components.

### IT Mapping Tool

There are specific tools that map IT networks and even the internet, automatically scanning servers and network devices in a relatively short time, depending on the size of the network. These tools inventory IT assets to discover security flaws such as misconfigured systems and permission settings, unpatched systems, etc. However, these tools are specific to IT networks and are not assemblers of more complex, cyber-physical systems that have different vulnerabilities, under different conditions specific to the infrastructure type, location, connections to other critical systems, and other factors.

### Lidar and Physical Mapping Tools

LiDAR (laser imaging, detection, and ranging) and other approaches for physical mapping create three dimensional representations of physical objects, including large objects such as the earth's surface. LiDAR instrument components typically consists of a laser, scanner, and GPS device. Applying LiDAR for large structures require transport a helicopter to acquire these images, increasing costs significantly. Intelligent Automation might leverage LiDAR and/or libraries of models to automatically assemble components for modeling and simulation.

### Computer Architecture

A database (e.g., 130) may comprise data entries (e.g., rows in a table). A database may comprise a processor, storage, memory, a network interface, a display, keyboard, etc. A database may be controlled by a database management system (DBMS). Collectively, the data entries, structural components, and DBMS are referred to as a database. Data within databases may be modeled in rows and columns in a series of tables to make processing and data querying efficient. Structured query language (SQL) may be used to write, query, and retrieve data. SQL is a programming language used by some relational databases to query, manipulate, and define data, and to provide access control. The database may take the form of a blockchain or relational database.

The Cyber Physical Human System (CPHS) 200 may include a hardware processor communicatively coupled to an instruction memory and to a data memory by a bus. The instruction memory can be configured to store, on at least a non-transitory computer readable medium as described in greater detail below, executable program code. The hardware processor may include multiple hardware processors and/or multiple processor cores. The hardware processor may include cooperation with hardware processors from different devices. The server, hub, and endpoint may execute one or more basic instructions included in the executable program code. The server, hub, and endpoint can include a network interface communicatively connected to the bus, for interfacing to a wide area network (WAN), e.g., the Internet or a private area network. Also communicatively connected to the bus can be a GUI. The CNA and/or data modeler may also include a mass storage, which can be accessible to the hardware processor via the bus.

The relationship between the executable program code and the hardware processor is structural; the executable program code is provided to the hardware processor by imparting various voltages at certain times across certain electrical connections, in accordance with binary values in the executable program code, to cause the hardware processor to perform some action, as now explained in more detail.

A hardware processor may be thought of as a complex electrical circuit that is configured to perform a predefined set of basic operations in response to receiving a corresponding basic instruction selected from a predefined native instruction set of codes. The predefined native instruction set of codes is specific to the hardware processor; the design of the processor defines the collection of basic instructions to which the processor will respond, and this collection forms the predefined native instruction set of codes. A basic instruction may be represented numerically as a series of binary values, in which case it may be referred to as a machine code. The series of binary values may be represented electrically, as inputs to the hardware processor, via electrical connections, using voltages that represent either a binary zero or a binary one. The hardware processor interprets the voltages as binary values.

Executable program code may therefore be understood to be a set of machine codes selected from the predefined native instruction set of codes. A given set of machine codes may be understood, generally, to constitute a module. A set of one or more modules may be understood to constitute an application program. An app may interact with the hardware processor directly or indirectly via an operating system. An app may be part of an operating system.

### Computer Program Product

A computer program product is an article of manufacture that has a computer-readable medium with executable program code that is adapted to enable a processing system to perform various operations and actions. A computer-readable medium may be transitory or non-transitory. A transitory computer-readable medium may be thought of as a conduit by which executable program code may be provided to a computer system, a short-term storage that may not use the data it holds other than to pass it on.

The buffers of transmitters and receivers that briefly store only portions of executable program code when being downloaded over the Internet is one example of a transitory computer-readable medium. A carrier signal or radio frequency signal, in transit, that conveys portions of executable program code over the air or through cabling such as fiber-optic cabling provides another example of a transitory computer-readable medium. Transitory computer-readable media convey parts of executable program code on the move, typically holding it long enough to just pass it on.

Non-transitory computer-readable media may be understood as a storage for the executable program code. Whereas a transitory computer-readable medium holds executable program code on the move, a non-transitory computer-readable medium is meant to hold executable program code at rest. Non-transitory computer-readable media may hold the software in its entirety, and for longer duration, compared to transitory computer-readable media that holds only a portion of the software and for a relatively short time. The term “non-transitory computer-readable medium” specifically excludes communication signals such as radio frequency signals in transit.

The following forms of storage exemplify non-transitory computer-readable media: removable storage such as a universal serial bus (USB) disk, a USB stick, a flash disk, a flash drive, a thumb drive, an external solid-state storage device (SSD), a compact flash card, a secure digital (SD) card, a diskette, a tape, a compact disc, an optical disc; secondary storage such as an internal hard drive, an internal SSD, internal flash memory, internal non-volatile memory, internal dynamic random-access memory (DRAM), read-only memory (ROM), random-access memory (RAM), and the like; and the primary storage of a computer system.

Different terms may be used to express the relationship between executable program code and non-transitory computer-readable media. Executable program code may be written on a disc, embodied in an application-specific integrated circuit, stored in a memory chip, or loaded in a cache memory, for example. Herein, the executable program code may be said, generally, to be stored in a computer-readable media. Conversely, the computer-readable media may be said to store, to include, to hold, or to have the executable program code.

### Creation of Executable Program Code

Software source code may be understood to be a human-readable, high-level representation of logical operations. Statements written in the C programming language provide an example of software source code.

Software source code, while sometimes colloquially described as a program or as code, is different from executable program code. Software source code may be processed, through compilation for example, to yield executable program code. The process that yields the executable program code varies with the hardware processor; software source code meant to yield executable program code to run on one hardware processor made by one manufacturer, for example, will be processed differently than for another hardware processor made by another manufacturer.

The process of transforming software source code into executable program code is known to those familiar with this technical field as compilation or interpretation and is not the subject of this application.

### User Interface

Generally, an interface (such as the component library user interface 212, model builder user interface 222, model library user interface 232) may be a web interface, electronic dashboard, or other access point to one or components that have functionality such as uploading data to the modelling system user send data, receive data, interact with a model, test a model, etc.

The CPHS modeling system 200 may include a user interface controller under control of the processing system that displays a user interface in accordance with a user interface module, i.e., a set of machine codes stored in the memory and selected from the predefined native instruction set of codes of the hardware processor, adapted to operate with the user interface controller to implement a user interface on a display device. Examples of a display device include a television, a projector, a computer display, a laptop display, a tablet display, a smartphone display, a smart television display, or the like.

The user interface may facilitate the collection of inputs from a user. The user interface may be graphical user interface with one or more user interface objects such as display objects and user activatable objects. The user interface may also have a touch interface that detects input when a user touches a display device.

A display object of a user interface may display information to the user. A user activatable object may allow the user to take some action. A display object and a user activatable object may be separate, collocated, overlapping, or nested one within another. Examples of display objects include lines, borders, text, images, or the like. Examples of user activatable objects include menus, buttons, toolbars, input boxes, widgets, and the like.

### Communications

The various networks are illustrated throughout the drawings and described in other locations throughout this disclosure, can comprise any suitable type of network such as the Internet or a wide variety of other types of networks and combinations thereof. For example, the network may include a wide area network (WAN), a local area network (LAN), a wireless network, an intranet, the Internet, a combination thereof, and so on. Further, although a single network is shown, a network can be configured to include multiple networks.

### Conclusion

For any computer-implemented embodiment, “means plus function” elements will use the term “means” the terns “logic” and “module” have the meaning ascribed to them above and are not to be construed as generic means. An interpretation under 35 U.S.C. § 112(f) is desired only where this description and/or the claims use specific terminology historically recognized to invoke the benefit of interpretation, such as means and the structure corresponding to a recited function, to include the equivalents thereof, as permitted to the fullest extent of the law and this written description, may include the disclosure, the accompanying claims, and the drawings, as they would be understood by one of skill in the art.

To the extent the subject matter has been described in language specific to structural features or methodological steps, it will be understood that the subject matter defined in the appended claims is not necessarily limited to the specific features or steps described. Rather, the specific features and steps are disclosed as example forms of implementing the claimed subject matter. To the extent headings appear in this description, they are for the convenience of the reader, not as limitations or restrictions of the systems, techniques, approaches, methods, or devices to those appearing in any section. Rather, the teachings and disclosures herein can be combined or rearranged with other portions of this disclosure and the knowledge of one of ordinary skill in the art. This disclosure generally encompasses and includes such variation. The indication of any elements or steps as optional does not indicate that all other or any other elements or steps are mandatory. The claims define the invention and form part of the specification. Limitations from the written description are not to be read into the claims.

Certain attributes, functions, steps of methods, or sub-steps of methods described herein may be associated with physical structures or components, such as a module of a physical device that, in implementations in accordance with this disclosure, make use of instructions (e.g., computer executable instructions) that may be embodied in hardware, such as an application-specific integrated circuit, or that may cause a computer (e.g., a general-purpose computer) executing the instructions to have defined characteristics. There may be a combination of hardware and software such as processor implementing firmware, software, and so forth, to function as a special purpose computer with the ascribed characteristics. For example, in embodiments a module may comprise a functional hardware unit (such as a self-contained hardware or software or a combination thereof) designed to interface the other components of a system such as through use of an application programming interface (API). In embodiments, structures for a module a module can be according to the modules function or set of functions, e.g., in accordance with a described algorithm. This disclosure may use nomenclature that associates a component or module with a function, purpose, step, or sub-step to identify the corresponding structure which, in instances, includes hardware and/or software that function for a specific purpose.

Titles and heading used throughout the specification are provided for navigational purposes only. They should not be considered as limiting or defining of the subject matter disclosed. Paragraphs and sections relevant to one figure or embodiment may be equally relevant to another figure.

While certain implementations have been described, these implementations have been presented by way of example only and are not intended to limit the scope of this disclosure. The novel devices, systems and methods described herein may be embodied in a variety of other forms; furthermore, various omissions, substitutions, and changes in the form of the devices, systems and methods described herein may be made without departing from the spirit of this disclosure.

The claimed subject matter is:

1. A CPHS modelling system for a building a high fidelity model of a cyber physical human system (CPHS) comprising:
an interface configured to receive a schema and operational data from a user;
a database configured to:
obtain information about the cyber physical human system from a library;
store information about the cyber physical human system in a partition;
an assembler configured to:
receive the schema;
receive the stored information;
generate a generic model of the cyber physical human system using the information from the database and schema; the generic model comprising an equation; and
a machine learning module configured to:
receive the operational data from the interface;
execute a machine learning process; and
use the operational data to generate the high fidelity model.

2. The CPHS modelling system of claim 1 comprising a server comprising a processor, memory and computer readable instructions; the computer readable instructions instructing the processor to communicate with the database, generate the interface, execute the assembler, and manage the machine learning module.

3. The CPHS modelling system of claim 1 wherein:
the library is an open library; and
the partition is publicly accessible.

4. The CPHS modelling system of claim 1 wherein the machine learning module is configured to identify a parameter required to generate the high fidelity model from the generic model.

5. The CPHS modelling system of claim 4 wherein the parameter comprises a nature, type, date, time, and quantity.

6. The CPHS modelling system of claim 4 wherein the machine learning module is configured to determine an improved value or define an undefined value for the parameter required to generate the high fidelity model from the generic model.

7. The CPHS modelling system of claim 6 wherein the machine learning module is configured to determine specific operational data required to determine the improved value or define the undefined value for the parameter.

8. The CPHS modelling system of claim 6 wherein the improved value for the parameter or the defined parameter is a value for the parameter that, when used in a calculation of the equation in the generic model, generates a model result that is closer to an actual result than a model result using a default value or undefined value for the parameter.

9. The CPHS modelling system of claim 6 wherein the machine learning module is configured to:
calculate a first model result by using a first value for the parameter to process the equation in the model;
determine an actual result from the operational data;
calculate a first difference in value between the first model result and actual result;
transform the parameter to a second value;
calculate a second model result by using the second value of the parameter to process the equation in the model;
calculate a second difference in value between the second model result and actual result;
determine the second difference has a lower value than the first difference; and
select the second value of the parameter for the high fidelity model.

10. The CPHS modelling system of claim 1 wherein the machine learning module is configured to:
receive a hyperparameter from the user; and
adjust the machine learning process based on the hyperparameter.

11. The CPHS modelling system of claim 1 wherein the machine learning module is configured to:
receive a hyperparameter from the user; and
switch the machine learning process from a first mode to a second mode; wherein the first mode utilizes a slower, more precise solver, and the second mode utilizes a faster, less precise solver.

12. The CPHS modelling system of claim 1 wherein the schema specifies components, interconnections between components, inputs to the components, and outputs to the components.

13. The CPHS modelling system of claim 12 comprises a schema converter configured to:
receive the schema in a signal structure format; and
convert the signal structure format schema to a substructure format schema.

14. The CPHS modelling system of claim 1 comprising a model sufficiency analyzer configured to:
determine what information is needed to generate a generic model;
determine whether public information in an open partition is sufficient to generate a generic model;
determine the public information from the open partition is not sufficient to generate the generic model; and
obtain proprietary information about the cyber physical human system from a proprietary source.

15. The CPHS modelling system of claim 14 wherein the database further configured to:
store the proprietary information about the cyber physical human system in a proprietary partition;
request permission from the proprietary source to use the proprietary information to generate a future model; and
store the proprietary information in a private partition; the private partition containing the proprietary information and previously stored private information.

16. The CPHS modelling system of claim 1 comprising a model sufficiency analyzer configured to:
determine the assembler cannot build the generic model based solely on public information in an open partition;
obtain proprietary information from a proprietary partition; and
supply the propriety information to the assembler.

17. The CPHS modelling system of claim 1 comprising a model sufficiency analyzer configured to:
determine the assembler cannot build the generic model based solely on the public information in the open partition;
obtain private information from a private partition; and
supply the private information to the assembler.

18. The CPHS modelling system of claim 1 comprising a data manager configured to divide the operational data into learning data, validation data, and test data.

19. A method of generating a high fidelity model of a cyber physical human system comprising:
receiving a schema and operational data from a user with an interface;
obtaining information about the cyber physical human system from a library;
storing information about the cyber physical human system into a partition of a database;
generating a generic model of the cyber physical human system using the information from the database and schema with an assembler; the generic model comprising an equation;
receiving the operational data from the interface;
executing a machine learning process with a machine learning module; and
using the operational data to generate the high fidelity model.

20. The method of claim 19 comprising a server communicating with the database; the server comprising a processor, memory and computer readable instructions; the processor executing the computer readable instructions to generate the interface, execute the assembler, and manage the machine learning module.

21. The method of claim 19 comprising identifying a parameter required to generate the high fidelity model from the generic model with the machine learning module.

22. The method of claim 21 wherein the parameter comprises a nature, type, date, time, and quantity.

23. The method of claim 21 comprising determining an improved value or defining an undefined value for the parameter required to generate the high fidelity model from the generic model.

24. The method of claim 23 comprising the machine learning module determining specific operational data required to determine the improved value or define the undefined value for the parameter.

25. The method of claim 23 comprising:
using a default value or undefined value for the parameter to determine a generic model result;
generating an improved model result using the improved value or defined value for the parameter; and
wherein the improved model result is closer to an actual result than the generic model result.

26. The method of claim 21 comprising:
calculating a first model result by using a first value for the parameter to process the equation in the generic model;
determining an actual result from the operational data;
calculate a first difference in value between the first model result and actual result;
transforming the parameter to a second value;
calculating a second model result by using the second value of the parameter to process the equation in the generic model;
calculating a second difference in value between the second model result and actual result;
determining the second difference has a lower value than the first difference; and
selecting the second value of the parameter for the high fidelity model.

27. The method of claim 19 comprising:
receiving a hyperparameter from the user; and
adjusting the machine learning process based on the hyperparameter.

28. The method of claim 19 comprising:
receiving a hyperparameter from the user; and
switching the machine learning process from a first mode to a second mode; wherein the first mode utilizes a slower, more precise solver, and the second mode utilizes a faster, less precise solver.

29. The method of claim 19 comprising specifies components, interconnections between components, inputs to the components and outputs to the components in the schema.

30. The method of claim 19 comprising:
receiving the schema in a signal structure format; and
converting the signal structure format to a substructure format.
